(19) United States
(12) Patent Application Publication
(10) Pub. No.: US 2026/0090375 A1
(43) Pub. Date: Mar. 26, 2026

(54) SEMICONDUCTOR PACKAGE INCLUDING HEAT TRANSFER STRUCTURE AND DAM STRUCTURE

(71) Applicant: SAMSUNG ELECTRONICS CO., LTD., Suwon-si (KR)

(72) Inventors: Dahye Kim, Suwon-si (KR); Kyung Don Mun, Suwon-si (KR); Sangjin Baek, Suwon-si (KR)

(73) Assignee: SAMSUNG ELECTRONICS CO., LTD., Suwon-si (KR)

(21) Appl. No.: 19/299,747

(22) Filed: Aug. 14, 2025

(30) Foreign Application Priority Data
Sep. 24, 2024 (KR) 10-2024-0129146

(51) Int. Cl. H01L 23/367; H01L 23/00; H01L 23/498; H01L 23/538; H01L 25/03

(52) U.S. Cl. CPC H10W 40/22; H10W 70/611; H10W 90/00; H10W 90/401; H10W 90/701; H10W 74/15; H10W 90/724; H10W 90/734

(57) ABSTRACT

A semiconductor package includes an upper redistribution layer, a first semiconductor chip on the upper redistribution layer, a heat radiator on the upper redistribution layer and horizontally spaced apart from the first semiconductor chip, a heat transfer structure between the upper redistribution layer and the heat radiator, and a dam structure between the upper redistribution layer and the heat radiator, where the dam structure includes a protruding portion that extends to a top surface of the upper redistribution layer, where the heat transfer structure includes a first heat transfer layer, and a second heat transfer layer adjacent to the first heat transfer layer, and in plan view, the dam structure is between the first heat transfer layer and the second heat transfer layer.

### CROSS-REFERENCE TO RELATED APPLICATION

This application is based on and claims priority to Korean Patent Application No. 10-2024-0129146, filed on Sep. 24, 2024, in the Korean Intellectual Property Office, the disclosure of which is incorporated by reference herein in its entirety.

### BACKGROUND

The present disclosure relates to a semiconductor package including a heat transfer structure and a dam structure.

With the recent advances in the electronics industry, the demand for electronic components with high performance, high speed, large capacity, and small size is increasing. To meet this demand, packaging technologies of mounting a plurality of semiconductor chips in a single package are being developed.

A semiconductor package may be configured to facilitate the use of an integrated circuit chip as a component in an electronic product. In general, the semiconductor package may include a printed circuit board (PCB) and a semiconductor chip, which is mounted on the PCB and is electrically connected to the PCB by bonding wires or bumps. With the recent development of the electronics industry, a semiconductor package technology is developing in various ways with the goal of miniaturization, weight reduction, and manufacturing cost reduction. For this, it may be necessary to develop packaging technologies of reducing a size and a weight of each component and of integrating a plurality of individual components in a single package.

As the operation speed and capacity of the semiconductor package increase, the power consumption of the semiconductor package is increasing. Thus, improving the thermal characteristics of the semiconductor package is becoming increasingly important.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Example embodiments provide a semiconductor package with improved thermal characteristics and improved stability, and a method of fabricating the same.

Additional aspects will be set forth in part in the description which follows and, in part, will be apparent from the description, or may be learned by practice of the presented embodiments.

According to an aspect of an example embodiment, a semiconductor package may include a lower redistribution layer, an outer connection terminal on a bottom surface of the lower redistribution layer, a first semiconductor chip on the lower redistribution layer, a mold layer enclosing the first semiconductor chip, an upper redistribution layer on the mold layer and over a top surface of the first semiconductor chip, a connection member connecting the lower redistribution layer and the upper redistribution layer, a second semiconductor chip on the upper redistribution layer, a heat radiator on the upper redistribution layer and horizontally spaced apart from the second semiconductor chip, the heat radiator including a center region and a peripheral region enclosing the center region, a heat transfer structure between the upper redistribution layer and the heat radiator, and a first dam structure between the upper redistribution layer and the heat radiator, where in plan view, the first dam structure has a closed-loop shape extending along a boundary between the center region and the peripheral region of the heat radiator, and the heat transfer structure includes a first heat transfer layer inside a perimeter of the first dam structure in plan view and filling a first region between the upper redistribution layer and the heat radiator, and a second heat transfer layer outside the perimeter of the first dam structure and filling a second region between the upper redistribution layer and the heat radiator.

According to an aspect of an example embodiment, a semiconductor package may include an upper redistribution layer, a first semiconductor chip on the upper redistribution layer, a heat radiator on the upper redistribution layer and horizontally spaced apart from the first semiconductor chip, a heat transfer structure between the upper redistribution layer and the heat radiator, and a dam structure between the upper redistribution layer and the heat radiator, where the dam structure includes a protruding portion that extends to a top surface of the upper redistribution layer, where the heat transfer structure includes a first heat transfer layer, and a second heat transfer layer adjacent to the first heat transfer layer, and in plan view, the dam structure is between the first heat transfer layer and the second heat transfer layer.

According to an aspect of an example embodiment, a semiconductor package may include a substrate, a first semiconductor chip on the substrate, a heat radiator on the substrate and horizontally spaced apart from the first semiconductor chip, the heat radiator comprising a center region and a peripheral region, at least one dam structure comprising a first dam structure between the substrate and the first semiconductor chip and, in plan view, overlapping a boundary between the center region and the peripheral region of the heat radiator, and a first heat transfer layer between the center region of the heat radiator and the substrate and within a perimeter of the first dam structure, where the first dam structure comprises a metallic material.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to one or more embodiments;

FIGS. 2 to 4 are plan views illustrating a semiconductor package according to one or more embodiments;

FIG. 5 is an enlarged cross-sectional view illustrating portion ‘N’ of FIG. 1 of a semiconductor package according to one or more embodiments;

FIG. 6 is a cross-sectional view illustrating a semiconductor package according to one or more embodiments;

FIG. 7 is a plan view illustrating a semiconductor package according to one or more embodiments;

FIGS. 8 and 9 are cross-sectional views illustrating a semiconductor package according to one or more embodiments; and

FIGS. 10 and 11 are cross-sectional views illustrating a method of fabricating a semiconductor package, according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

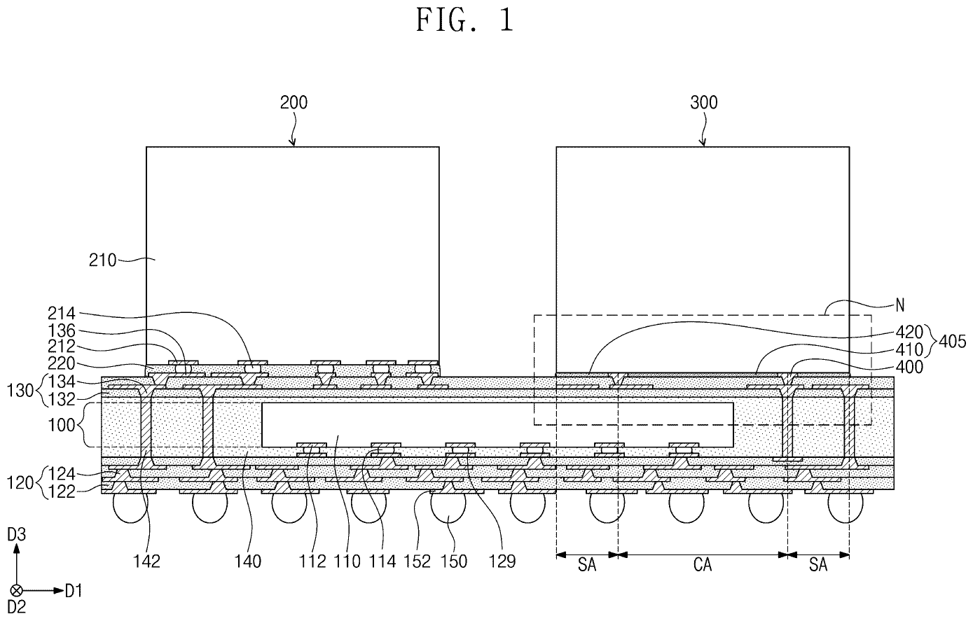

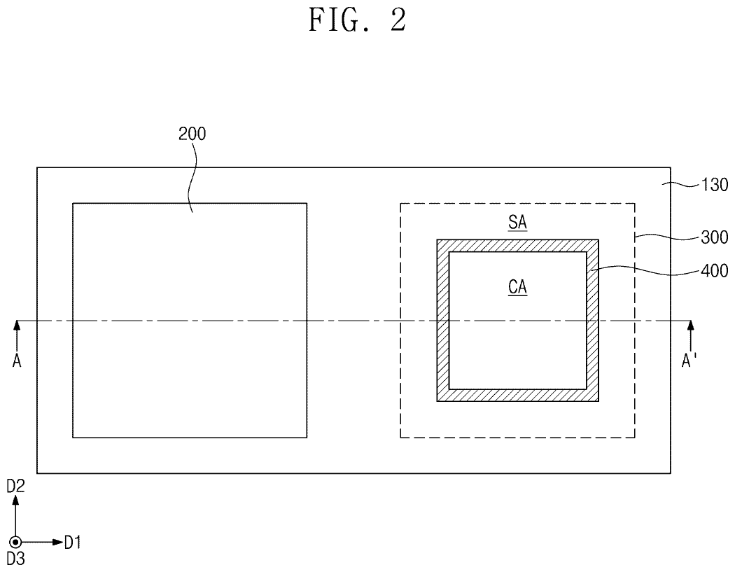

FIG. 1 is a cross-sectional view illustrating a semiconductor package according to one or more embodiments. FIG. 2 is a plan view illustrating a semiconductor package according to one or more embodiments. FIG. 1 is a cross-sectional view taken along a line A-A′ of FIG. 2. Hereinafter, the directions D1, D2, and D3 of FIG. 1, which are perpendicular to each other, may be referred to as first, second, and third directions, respectively.

Referring to FIG. 1, a lower redistribution layer 120 may be provided. The lower redistribution layer 120 may include at least one lower interconnection layer. Each of the lower interconnection layers may include a lower insulating pattern 122 and a lower interconnection pattern 124. The lower interconnection patterns 124, which are included in adjacent lower interconnection layers, may be electrically connected to each other. Hereinafter, the lower insulating pattern 122 and the lower interconnection pattern 124 will be described in detail with reference to one of the lower interconnection layers.

The lower insulating pattern 122 may be formed of or include at least one of insulating polymers and photoimageable polymers (PIDs). For example, the PID materials may include at least one of photoimageable polyimides, polybenzoxazole (PBO), phenol-based polymers, and benzocyclobutene-based polymers.

The lower interconnection pattern 124 may be provided on the lower insulating pattern 122. The lower interconnection pattern 124 may be provided on a bottom surface of the lower insulating pattern 122. The lower interconnection pattern 124 may include a protruding portion that extends to a region on the bottom surface of the lower insulating pattern 122. The lower interconnection pattern 124 may be horizontally extended, on the bottom surface of the lower insulating pattern 122. On the bottom surface of the lower insulating pattern 122, the lower interconnection pattern 124 may be covered with the lower insulating pattern 122 of another lower interconnection layer thereunder. As described above, the lower interconnection pattern 124 may be a pad portion or a wire portion of the lower interconnection layer. That is, the lower interconnection pattern 124 may be an element that is used for horizontal redistribution in the lower redistribution layer 120. The lower interconnection pattern 124 may include a conductive material. For example, the lower interconnection pattern 124 may be formed of or include copper (Cu).

The lower interconnection pattern 124 may have a damascene structure. For example, the lower interconnection pattern 124 may include a via portion, which extends upward from the top surface thereof. The via portion may be used to vertically connect the lower interconnection patterns 124, which are respectively included in adjacent the lower interconnection layers, to each other. For example, the via portion may extend from the top surface of the lower interconnection pattern 124 to penetrate the lower insulating pattern 122 and may be coupled to a bottom surface of the lower interconnection pattern 124 of another lower interconnection layer thereon. In other words, a lower portion of the lower interconnection pattern 124, which is placed below the lower insulating pattern 122, may be a head portion, which is used as a horizontal wire or a pad, and the via portion of the lower interconnection pattern 124 may be a tail portion. The lower interconnection pattern 124 may have an inverted shape of the letter ‘T’.

A first substrate pad 129 may be provided on a top surface of the lower redistribution layer 120. Here, the first substrate pad 129 may be a portion of the lower interconnection pattern 124, which protrudes to a region on the top surface of the lower redistribution layer 120, or an additional pad, which is disposed on the lower insulating pattern 122 of the lower redistribution layer 120 and is connected to the lower interconnection pattern 124. However, embodiments are not limited thereto, and in one or more embodiments, the first substrate pad 129 may be coplanar with the top surface of the lower redistribution layer 120 and may be exposed to a region on the top surface of the lower redistribution layer 120. In one or more embodiments, a plurality of first substrate pads may be provided.

An outer connection terminal 150 may be provided below the lower redistribution layer 120. The outer connection terminal 150 may be disposed on a second substrate pad 152 provided on a bottom surface of the lower redistribution layer 120. Here, the second substrate pad 152 may be a portion of the lower interconnection pattern 124, which protrudes to a region on the bottom surface of the lower redistribution layer 120, or an additional pad, which is disposed on the lower insulating pattern 122 of the lower redistribution layer 120 and is connected to the lower interconnection pattern 124. However, embodiments are not limited thereto, and in one or more embodiments, the second substrate pad 152 may be coplanar with the bottom surface of the lower redistribution layer 120 and may be exposed to a region on the bottom surface of the lower redistribution layer 120. The outer connection terminal 150 may include solder balls or solder bumps. In one or more embodiments, a plurality of second substrate pads and a plurality of outer connection terminals 150 may be provided.

A first semiconductor chip 100 may be provided on (e.g., on the top surface of) the lower redistribution layer 120. The first semiconductor chip 100 may be provided on the lower redistribution layer 120 in a face down manner. A bottom surface of the first semiconductor chip 100 may be an active surface.

The first semiconductor chip 100 may include a first semiconductor substrate 110. The first semiconductor substrate 110 may include a semiconductor material. As an example, the first semiconductor substrate 110 may include silicon (Si). An integrated device or integrated circuits may be formed on a bottom surface of the first semiconductor substrate 110. The first semiconductor chip 100 may be used by a processor, which is configured to process and/or control data, or may be included in a processor. Here, the processor may include, for example, a central processing unit (CPU), a micro controller unit (MCU), an application processor (AP), an electronic controlling unit (ECU), a micro-processor, and/or at least one electronic device, which is configured to process various calculation operations and generate various control signals.

The first semiconductor chip 100 may include a first chip pad 112 provided on the bottom surface of the first semiconductor chip 100. The first chip pad 112 may be electrically connected to the integrated device or the integrated circuits in the first semiconductor chip 100.

A first connection terminal 114 (e.g., solder balls or solder bumps) may be provided on the first chip pad 112 of the first semiconductor chip 100. The first connection terminal 114 may be provided between the first substrate pad 129 and the first chip pad 112. The first semiconductor chip 100 may be mounted on the first substrate pad 129 of the lower redistribution layer 120 using the first connection terminal 114. In other words, the first semiconductor chip 100 may be mounted on the lower redistribution layer 120 in a flip chip bonding manner. In one or more embodiments, a plurality of first chip pads 112 and a plurality of first connection terminals may be provided.

A mold layer 140 may be provided on the lower redistribution layer 120. The mold layer 140 may cover the top surface of the lower redistribution layer 120. The mold layer 140 may enclose the first semiconductor chip 100. The mold layer 140 may enclose the first substrate pad 129 and the first connection terminal 114. The mold layer 140 may cover the first semiconductor chip 100. The mold layer 140 may include an insulating material. For example, the mold layer 140 may include an epoxy molding compound (EMC).

An upper redistribution layer 130 may be provided on a top surface of the mold layer 140. The upper redistribution layer 130 may cover the top surface of the mold layer 140. In one or more embodiments, the upper redistribution layer 130 may include at least two upper interconnection layers, which are sequentially stacked on the top surface of the mold layer 140. Each upper interconnection layer may include an upper insulating pattern 132 and an upper interconnection pattern 134. The upper interconnection patterns 134, which are included in adjacent upper interconnection layers, may be electrically connected to each other. Hereinafter, the upper insulating pattern 132 and the upper interconnection pattern 134 will be described in detail with reference to one of the upper interconnection layers.

The upper insulating pattern 132 may be formed of or include at least one of insulating polymers and photoimageable dielectric (PID) materials. For example, photoimageable dielectric (PID) material may include at least one of photoimageable polyimide (PI), polybenzoxazole (PBO), phenol-based polymers, or benzocyclobutene-based polymers.

The upper interconnection pattern 134 may be provided on the upper insulating pattern 132. The upper interconnection pattern 134 may be provided on a top surface of the upper insulating pattern 132. The upper interconnection pattern 134 may include a protruding portion that extends to a region on the top surface of the upper insulating pattern 132. The upper interconnection pattern 134 may be horizontally extended, on the top surface of the upper insulating pattern 132. The upper interconnection pattern 134 may be covered with the upper insulating pattern 132 of another upper interconnection layer thereon. As described above, the upper interconnection pattern 134 may be a pad portion or a wire portion of the upper interconnection layer. That is, the upper interconnection pattern 134 may be an element, which is used for horizontal redistribution in the upper redistribution layer 130. The upper interconnection pattern 134 may include a conductive material. For example, the upper interconnection pattern 134 may include copper (Cu).

The upper interconnection pattern 134 may have a damascene structure. For example, the upper interconnection pattern 134 may have a via portion that protrudes to a region on a bottom surface thereof. The via portion may be used to vertically connect the upper interconnection patterns 134, which are respectively included in adjacent upper interconnection layers, to each other. For example, the via portion may extend from the bottom surface of the upper interconnection pattern 134 to penetrate the upper insulating pattern 132 and may be connected to a top surface of the upper interconnection pattern 134 of another upper interconnection layer thereunder. That is, an upper portion of the upper interconnection pattern 134, which is placed on the upper insulating pattern 132, may be a head portion, which is used as a horizontal wire or a pad, and the via portion of the upper interconnection pattern 134 may be a tail portion. The via portion of the upper interconnection pattern 134 may be electrically connected to the via portion of the lower interconnection pattern 124 through a metal post 142, which will be described below. The upper interconnection pattern 134 may have a shape of the letter ‘T’.

A third substrate pad 136 may be provided on a top surface of the upper redistribution layer 130. Here, the third substrate pad 136 may be a portion of the upper interconnection pattern 134, which protrudes to a region on the top surface of the upper redistribution layer 130, or an additional pad, which is disposed on the upper insulating pattern 132 of the upper redistribution layer 130 and is connected to the upper interconnection pattern 134. However, embodiments are not limited thereto, and in one or more embodiments, the third substrate pad 136 may be coplanar with the top surface of the upper redistribution layer 130 and may be exposed to a region on the top surface of the upper redistribution layer 130. In one or more embodiments, a plurality of third substrate pads may be provided. The third substrate pad 136 may be the head portion of the upper interconnection pattern 134, which is placed in the uppermost one of the upper interconnection layers. In one or more embodiments, a width of the third substrate pad 136 in the first direction D1 may range from 150 μm to 250 μm.

The semiconductor package may include the metal post 142. The metal post 142 may be disposed to be horizontally spaced apart from the first semiconductor chip 100. That is, the metal post 142 may correspond to a connection member, which is provided near the first semiconductor chip 100 to connect the lower redistribution layer 120 to the upper redistribution layer 130. The metal post 142 may be provided to vertically penetrate the mold layer 140. An end of the metal post 142 may be connected to at least a portion of the lower interconnection pattern 124 of the lower redistribution layer 120, and an opposite end of the metal post 142 may be connected to at least a portion of the upper interconnection pattern 134 of the upper redistribution layer 130. A width of the metal post 142 may increase as a distance from the lower redistribution layer 120 or upper redistribution layer 130 increases. For example, the metal post 142 may have a tapered shape in a specific direction. The metal post 142 may have a relatively straight pattern that has a line-shaped section and has a constant width in a vertical direction. A seed layer/barrier layer may be provided between the metal post 142 and the mold layer 140. For example, the seed layer/barrier layer may cover a bottom or side surface of the metal post 142. In one or more embodiments, a plurality of metal posts 142 may be provided. The metal post 142 may include a metallic material. The metallic material may include copper (Cu), aluminum (Al), silver (Ag), tin (Sn), gold (Au), nickel (Ni), lead (Pb), titanium (Ti), or alloys thereof.

A second semiconductor chip 200 may be provided on the top surface of the upper redistribution layer 130. The second semiconductor chip 200 may be provided on the upper redistribution layer 130 in a face down shape. A bottom surface of the second semiconductor chip 200 may be an active surface of the second semiconductor chip 200.

The second semiconductor chip 200 may include a second semiconductor substrate 210. The second semiconductor substrate 210 may include a semiconductor material. In one or more embodiments, the second semiconductor substrate 210 may include silicon (Si). An integrated device or integrated circuits may be formed on a bottom surface of the second semiconductor substrate 210. The integrated device or the integrated circuits may include a memory circuit. In other words, the second semiconductor chip 200 may be a memory chip. However, embodiments are not limited thereto.

The second semiconductor chip 200 may include a second chip pad 212 provided on the bottom surface of the second semiconductor chip 200. The second chip pad 212 may be electrically connected to the integrated device or integrated circuits in the second semiconductor chip 200.

A second connection terminal 214 (e.g., solder balls or solder bumps) may be provided on the second chip pad 212 of the second semiconductor chip 200. The second connection terminal 214 may be provided between the third substrate pad 136 and the second chip pad 212. The second semiconductor chip 200 may be mounted on the third substrate pad 136 of the upper redistribution layer 130 using the second connection terminals. In other words, the second semiconductor chip 200 may be mounted on the upper redistribution layer 130 in a flip chip bonding method. In one or more embodiments, a plurality of second chip pads 212 and a plurality of second connection terminals may be provided.

An under-fill layer 220 may be provided between the upper redistribution layer 130 and the second semiconductor chip 200. The under-fill layer 220 may fill a region between the upper redistribution layer 130 and the second semiconductor chip 200 and may enclose the third substrate pad 136 and the second connection terminal 214.

A heat radiator 300 may be provided on the top surface of the upper redistribution layer 130 with a heat transfer structure 405 therebetween. The heat radiator 300 may be horizontally spaced apart from the second semiconductor chip 200. The heat radiator 300 may be configured to transfer the heat, which is generated from the first and second semiconductor chips 100 and 200, to the outside.

The heat radiator 300 may be formed of or include at least one of metallic materials, ceramic materials, carbon-containing materials, and polymer materials having high thermal conductivity. The heat radiator 300 may be provided to have an uneven structure, if necessary. The heat, which is generated from the first and second semiconductor chips 100 and 200, may be quickly dissipated to an outer region on the upper redistribution layer 130 through the heat radiator 300 with a large sectional area.

The heat radiator 300 may include a center region CA and a peripheral region SA enclosing the center region CA. A heat transfer structure 405 may be provided between the heat radiator 300 and the upper redistribution layer 130. The heat transfer structure 405 may include a first heat transfer layer 410 and a second heat transfer layer 420. The center region CA of the heat radiator 300 may refer to a region, on which a first heat transfer layer 410 is provided. Although this region is referred to as the center region CA, it is not limited to a region on the center of the heat radiator 300, and any region of the heat radiator 300 located on the first heat transfer layer 410 may be defined as the center region CA. The peripheral region SA of the heat radiator 300 may refer to a region enclosing the center region CA (i.e., a region enclosing the perimeter of the center region CA in a plan view). In addition, although this region is referred to as the peripheral region SA, it is not limited to a region on an edge of the heat radiator 300, and a remaining region, except for the center region CA, or a region of the heat radiator 300 located on a second heat transfer layer 420 to be described below may be defined as the peripheral region SA. The center and peripheral regions CA and SA may contact each other. For example, the center and peripheral regions CA and SA may contact each other and may be provided to have an interface therebetween.

A first dam structure 400 may be provided on the top surface of the upper redistribution layer 130. The first dam structure 400 may include a protruding portion that extends to a region on the top surface of the upper redistribution layer 130. The first dam structure 400 may have outer and inner side surfaces that are opposite to each other and have a flat shape. In a plan view, the first dam structure 400 may have a closed-loop shape. More specifically, in a plan view, the first dam structure 400 may have a tetragonal ring shape. In a plan view, the first dam structure 400 may overlap a boundary between the center and peripheral regions CA and SA of the heat radiator 300. The first dam structure 400 may extend along the boundary between the center and peripheral regions CA and SA of the heat radiator 300. The first dam structure 400 may define the center and peripheral regions CA and SA of the heat radiator 300. In other words, an inner region of the first dam structure 400 defined by the inner side surface of the first dam structure 400, may overlap the center region CA of the heat radiator 300. In a plan view, an outer region of the first dam structure 400 which is defined by the outer side surface of the first dam structure 400 and the side surfaces of the heat radiator 300, may overlap the peripheral region SA of the heat radiator 300. A width of the first dam structure 400 in the first direction D1 may be smaller than a width of the third substrate pad 136 in the first direction D1. As an example, the width of the first dam structure 400 in the first direction D1 may range from 30 μm to 70 μm. A height of the first dam structure 400 in the third direction D3 may range from 30 μm to 60 μm. The height of the first dam structure 400 may be equal to or smaller than a distance from the top surface of the upper redistribution layer 130 to the bottom surface of the heat radiator 300. In one or more embodiments, a top surface of the first dam structure 400 may contact the bottom surface of the heat radiator 300. The contact surface between the heat radiator 300 and the first dam structure 400 may be flat. However, embodiments are not limited thereto, and in one or more embodiments, first and second heat transfer layers 410 and 420 may be provided to cover at least a portion of the top surface of the first dam structure 400. Here, the heat radiator 300 may be attached to the first dam structure 400 by the first and second heat transfer layers 410 and 420 on the top surface of the first dam structure 400.

The first dam structure 400 may be formed of or include at least one of metallic materials (e.g., nickel (Ni), copper (Cu), gold (Au), aluminum (Al), and tungsten (W)). In one or more embodiments, the first dam structure 400 may include two layers that are vertically stacked. A lower layer of the two layers may include copper (Cu). An upper layer of the two layers may include at least one of nickel (Ni) or gold (Au). However, embodiments are not limited thereto, and in one or more embodiments, the first dam structure 400 may be composed of three or more layers or a single layer. The first dam structure 400 may be formed of or include the same material as the third substrate pad.

The first and second heat transfer layers 410 and 420 may be disposed on the top surface of the upper redistribution layer 130. The first heat transfer layer 410 may be provided on the center region CA of the heat radiator 300. The first heat transfer layer 410 may be disposed on the top surface of the upper redistribution layer 130 and in the inner region of the first dam structure 400 (i.e., within the perimeter of the first dam structure 400). The inner side surface of the first dam structure 400 may contact a side surface of the first heat transfer layer 410. In other words, the first heat transfer layer 410 may be interposed between inner side surfaces of the first dam structure 400. In a plan view, the first dam structure 400 may enclose the first heat transfer layer 410. The first heat transfer layer 410 may fill a region between the heat radiator 300 and the upper redistribution layer 130. More specifically, the first heat transfer layer 410 may fill a region between a center region CA of the bottom surface of the heat radiator 300 and the upper redistribution layer 130. The first heat transfer layer 410 may cover a portion of the top surface of the upper redistribution layer 130. A top surface of the first heat transfer layer 410 may contact the center portion of the bottom surface of the heat radiator 300. The first heat transfer layer 410 may include a protruding portion that extends to a region on the top surface of the first dam structure 400. The first heat transfer layer 410 may cover at least a portion of the top surface of the first dam structure 400. However, embodiments are not limited thereto.

The first heat transfer layer 410 may have a higher thermal conductivity than the air. The first heat transfer layer 410 may include a thermal interface material (TIM). The thermal interface material may include, for example, a polymer and thermally conductive particles. The thermally conductive particles may be dispersed in the polymer. In one or more embodiments, the size of the thermally conductive particles may range from 20 μm to 50 μm. The thermal conductivity of the first heat transfer layer 410 may range from 6 W/mK to 7 W/mK. The adhesion strength of the first heat transfer layer 410 may range from 0.5 kgf/cm² to 10 kgf/cm².

The second heat transfer layer 420 may be disposed on the top surface of the upper redistribution layer 130 and outside the first dam structure 400. In a plan view, the second heat transfer layer 420 may be provided in the peripheral region SA of the heat radiator 300. A side surface of the second heat transfer layer 420 may contact the outer side surface of the first dam structure 400. In a plan view, the second heat transfer layer 420 may be provided to enclose the first dam structure 400 (e.g., the second heat transfer layer 420 may enclose the first dam structure 400 and may surround the perimeter of the first dam structure 40). The second heat transfer layer 420 may fill a region between the heat radiator 300 and the upper redistribution layer 130. More specifically, the second heat transfer layer 420 may fill a region between the peripheral region SA of the bottom surface of the heat radiator 300 and the upper redistribution layer 130. Here, the peripheral region SA of the bottom surface of the heat radiator 300 may be a remaining region of the bottom surface of the heat radiator 300, except for the center region CA. That is, the second heat transfer layer 420 may fill a region between the heat radiator 300 and the upper redistribution layer 130, except for the region provided with the first heat transfer layer 410. The second heat transfer layer 420 may cover a portion of the upper redistribution layer 130. A top surface of the second heat transfer layer 420 may contact the peripheral region SA of the bottom surface of the heat radiator 300. In one or more embodiments, the first heat transfer layer 410 may fill a region between the upper redistribution layer 130 and the center region CA of the heat radiator 300, and the second heat transfer layer 420 may fill a region between the upper redistribution layer 130 and the peripheral region SA of the heat radiator 300. The second heat transfer layer 420 may include a protruding portion that extends to a region on the top surface of the first dam structure 400. The second heat transfer layer 420 may cover at least a portion of the top surface of the first dam structure 400, but embodiments are not limited thereto.

The second heat transfer layer 420 may have a higher thermal conductivity than the air. The second heat transfer layer 420 may include a thermal interface material (TIM). The thermal interface material may include, for example, a polymer and thermally conductive particles. The thermally conductive particles may be dispersed in the polymer. The size of the thermally conductive particles in the second heat transfer layer 420 may be smaller than the size of the thermally conductive particles in the first heat transfer layer 410. In one or more embodiments, the size of the thermally conductive particles in the second heat transfer layer 420 may range from 0.1 μm to 15 μm. The thermal conductivity of the second heat transfer layer 420 may be smaller than the thermal conductivity of the first heat transfer layer 410. In one or more embodiments, the thermal conductivity of the second heat transfer layer 420 may range from 1 W/mK to 2 W/mK. The adhesion strength of the second heat transfer layer 420 may be stronger than the adhesion strength of the first heat transfer layer 410. In one or more embodiments, the adhesion strength of the second heat transfer layer 420 may range from 0.5 kgf/cm² to 10 kgf/cm².

A bottom surface of each of the first and second heat transfer layers 410 and 420 may contact the top surface of the upper redistribution layer 130, and the top surface of each of the first and second heat transfer layers 410 and 420 may contact the bottom surface of the heat radiator 300. The top surfaces of the first and second heat transfer layers 410 and 420 may be coplanar with each other. The first and second heat transfer layers 410 and 420 may be used to attach the heat radiator 300 to the upper redistribution layer 130.

The first dam structure 400 may be provided to separate two different regions, in which the first and second heat transfer layers 410 and 420 are respectively provided, on the upper redistribution layer 130. In a plan view, the first dam structure 400 may be provided between the first and second heat transfer layers 410 and 420. In other words, the first dam structure 400 may be placed between the two regions for the first and second heat transfer layers 410 and 420, such that the first heat transfer layer 410 is within the perimeter of the first dam structure 400, and the second heat transfer layer 420 is outside the perimeter of the first dam structure 400.

Since the first heat transfer layer 410 having the high thermal conductivity is disposed on the center region CA of the heat radiator 300 and the second heat transfer layer 420 having the high adhesion strength is disposed on the peripheral region SA of the heat radiator 300, the semiconductor package may be fabricated to have high heat-dissipation efficiency and high stability. Due to the high thermal conductivity of the first heat transfer layer 410, heat, which is generated from the first and second semiconductor chips 100 and 200, may be efficiently exhausted to the outside, and due to the high adhesion strength of the second heat transfer layer 420, the heat radiator 300 may be stably attached to the upper redistribution layer 130.

FIGS. 1 and 2 illustrate an example, in which the first and second heat transfer layers 410 and 420 are respectively disposed on the center and peripheral regions CA and SA of the heat radiator 300, but embodiments are not limited thereto. The positions of the first and second heat transfer layers 410 and 420 may be exchanged. For example, the second heat transfer layer 420 may be disposed in the inner region of the first dam structure 400 to fill a space between the upper redistribution layer 130 and the center region CA of the heat radiator 300, and the first heat transfer layer 410 may be disposed in the outer region of the first dam structure 400 to fill a space between the upper redistribution layer 130 and the peripheral region SA of the heat radiator 300.

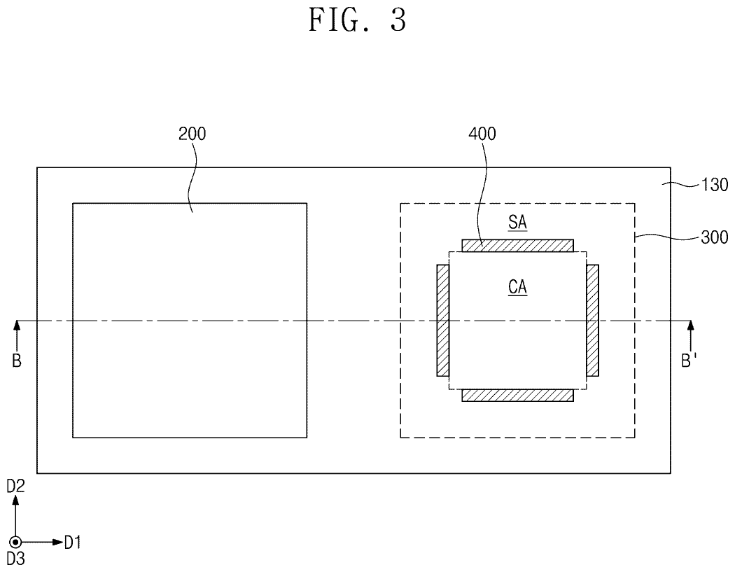

FIG. 3 is a plan view illustrating a semiconductor package according to one or more embodiments. FIG. 1 may also be a cross-sectional view taken along line B-B′. In the embodiment of FIGS. 1 and 2, the first dam structure 400 is illustrated to have a ring shape or a closed-curve shape enclosing the first heat transfer layer 410, but embodiments are not limited thereto.

Referring to FIG. 3, the arrangement and number of the first dam structure 400 may be variously changed. For example, a plurality of first dam structures 400 may be provided. In one or more embodiments, the first dam structures 400 may be placed around the first heat transfer layer 410 to be spaced apart from each other. For example, the first heat transfer layer 410 may be disposed between the first dam structures 400. In detail, at least one first dam structure 400 may be disposed at an edge of the first heat transfer layer 410 in such a way that inner side surfaces of the first dam structures 400 contact the first heat transfer layer 410. As an example, each of the four side surfaces of the first heat transfer layer 410 may contact the inner side surface of each of the first dam structures 400.

The first dam structures 400 may not fully enclose the first heat transfer layer 410, in a plan view. For example, the first dam structures 400 may be provided to partially enclose the side surfaces or corners of the first heat transfer layer 410, but not all of the four side surfaces of the first heat transfer layer 410. The first dam structures 400 may be provided to form a closed, non-tetragonal shape or a partially-open shape (e.g., a C shape or angular C-shape), in a plan view.

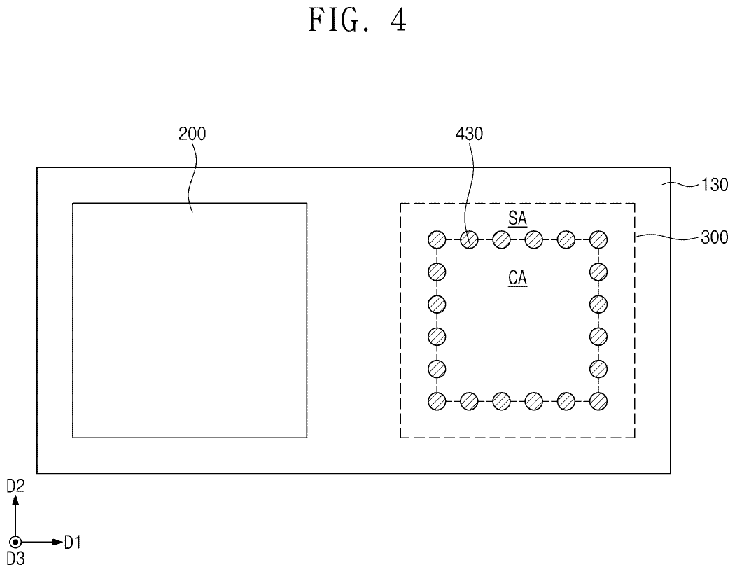

FIG. 4 is a plan view illustrating a semiconductor package according to one or more embodiments. The semiconductor package of FIG. 4 may have the same or similar structural elements included in the semiconductor package shown in FIGS. 2 and 3, and thus, duplicate descriptions thereof may be omitted. In the embodiment of FIGS. 1 and 2, the first dam structure 400 is illustrated to have a ring shape or a closed-curve shape enclosing the first heat transfer layer 410, but embodiments are not limited thereto.

In one or more embodiments, a plurality of first dam structures 400 may be provided. The first dam structures 400 may include a plurality of connection pads 430. The connection pads 430 may be disposed along the edge of the first heat transfer layer 410 to be spaced apart from each other by a specific distance. The first heat transfer layer 410 may be disposed between the connection pads 430. In a plan view, the connection pads 430 may be arranged along the boundary between the center and peripheral regions CA and SA of the heat radiator 300. In other words, the connection pads 430 may overlap the boundary between the center and peripheral regions CA and SA of the heat radiator 300.

Each of the connection pads 430 may have the same or similar shape as the third substrate pad 136. For example, the connection pads 430 may have a circular shape, in a plan view, but embodiments are not limited thereto. A width of each of the connection pads 430 in the first direction D1 may be equal to or less than a width of the third substrate pad 136 in the first direction D1. In one or more embodiments, the width of the connection pads 430 may range from 30 μm to 70 μm. A height of each of the connection pads 430 in the third direction D3 may range from 30 μm to 60 μm.

The connection pads 430 may be formed of or include at least one of metallic materials (e.g., nickel (Ni), copper (Cu), gold (Au), aluminum (Al), and tungsten (W)). In one or more embodiments, the connection pads 430 may include two layers that are vertically stacked. A lower layer of the two layers may include copper (Cu). An upper layer of the two layers may include at least one of nickel (Ni) or gold (Au). However, embodiments are not limited thereto, the connection pads 430 may be composed of three or more layers or a single layer. The connection pads 430 may be formed of or include the same material as the third substrate pad.

The connection pads 430 may not fully enclose the first heat transfer layer 410, in a plan view. The connection pads 430 may be provided to partially enclose the side surfaces or corners of the first heat transfer layer 410, but not all of the four side surfaces of the first heat transfer layer 410.

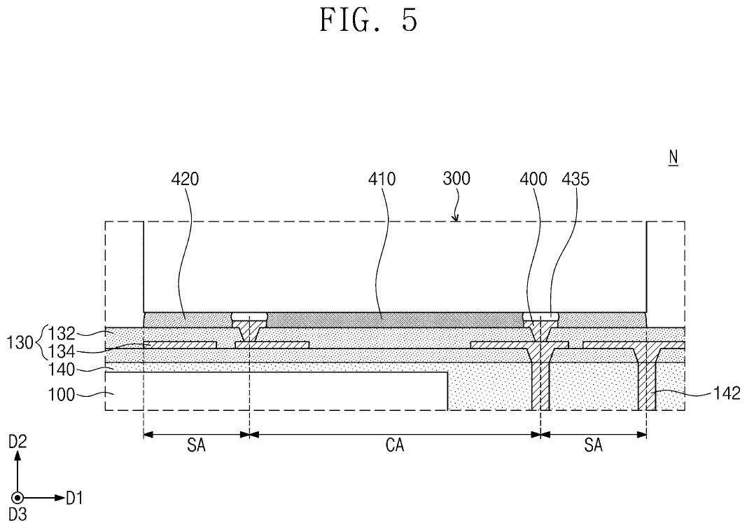

FIG. 5 is an enlarged cross-sectional view illustrating a dam structure according to one or more embodiments and corresponding to a portion ‘N’ of FIG. 1. FIG. 1 illustrates an example, in which the top surface of the first dam structure 400 contacts the bottom surface of the heat radiator 300 or the first and second heat transfer layers 410 and 420 cover a portion of the top surface of the first dam structure 400, but embodiments are not limited thereto. For example, as shown in FIG. 5, a third connection terminal 435, such as a solder ball or solder bump, may be provided on the top surface of the first dam structure 400. The third connection terminal 435 may be provided between the first dam structure 400 and the heat radiator 300. A bottom surface of the third connection terminal 435 may contact the top surface of the first dam structure 400. A top surface of the third connection terminal 435 may contact the bottom surface of the heat radiator 300. The heat radiator 300 may be attached to the first dam structure 400 using the third connection terminal 435. In one or more embodiments, a plurality of third connection terminals 435 may be provided. As an example, the plurality of third connection terminals 435 may be disposed to be spaced apart from each other on the top surface of the first dam structure 400. The number and arrangement of the third connection terminals may be variously changed, if necessary.

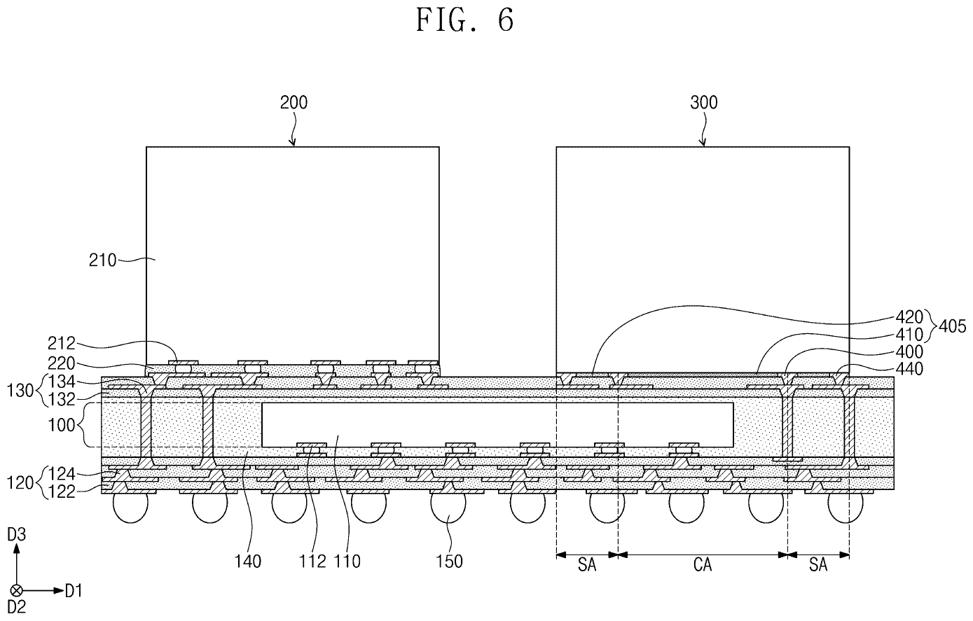

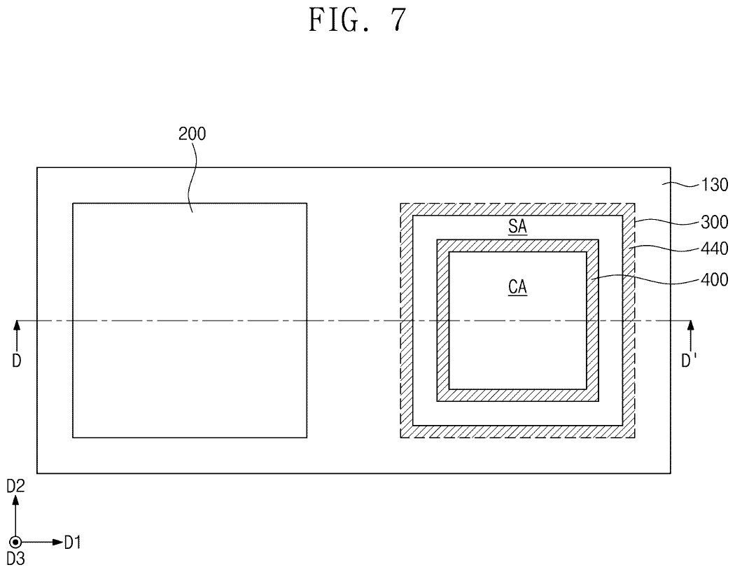

FIG. 6 is a cross-sectional view illustrating a semiconductor package according to one or more embodiments. FIG. 7 is a plan view illustrating a semiconductor package according to one or more embodiments, and FIG. 6 is a sectional view taken along a line D-D′ of FIG. 7. Description of aspects that are the same as or similar to those described above may be omitted.

Referring to FIG. 6, a second dam structure 440 may be provided on the top surface of the upper redistribution layer 130. The second dam structure 440 may include a protruding portion that extends to a region on the top surface of the upper redistribution layer 130. The second dam structure 440 may be provided between the heat radiator 300 and the upper redistribution layer 130. More specifically, the second dam structure 440 may be interposed between the peripheral region SA of the bottom surface of the heat radiator 300 and the upper redistribution layer 130. The second dam structure 440 may be provided on the peripheral region SA of the heat radiator 300. In a plan view, the second dam structure 440 may extend along an edge of the heat radiator 300. The second dam structure 440 may be vertically aligned to the side surfaces of the heat radiator 300. However, embodiments are not limited thereto. For example, in a plan view, an outer side surface of the second dam structure 440 may protrude to a region outside the side surfaces of the heat radiator 300 or may be placed in a region inside the side surfaces of the heat radiator 300. In a plan view, the second dam structure 440 may have a closed-loop shape. The second dam structure 440 may have outer and inner side surfaces that are opposite to each other and have a flat shape. In one or more embodiments, the second dam structure 440 may have a tetragonal ring shape, in a plan view.

In a plan view, the second dam structure 440 may be provided to enclose the first dam structure 400 and may be spaced apart from the first dam structure 400. The first and second dam structures 400 and 440 may define the center and peripheral regions CA and SA of the heat radiator 300. For example, an inner region of the first dam structure 400, which is defined by the inner side surface of the first dam structure 400, may overlap the center region CA of the heat radiator 300. In a plan view, a region, which is defined by the outer side surface of the first dam structure 400 and the inner side surface of the second dam structure 440, may overlap the peripheral region SA of the heat radiator 300.

A width and a height of the second dam structure 440, which are respectively measured in the first and third directions D1 and D3, may be equal to those of the first dam structure 400, but embodiments are not limited thereto. For example, the width of the second dam structure 440 may range from 30 μm to 70 μm. The height of the second dam structure 440 may range from 30 μm to 60 μm. The height of the second dam structure 440 may be equal to or smaller than a distance from the top surface of the upper redistribution layer 130 to the bottom surface of the heat radiator 300. As an example, a top surface of the second dam structure 440 may contact the bottom surface of the heat radiator 300. The contact surface between the heat radiator 300 and the second dam structure 440 may be flat.

The second dam structure 440 may be formed of or include at least one of metallic materials (e.g., nickel (Ni), copper (Cu), gold (Au), aluminum (Al), and tungsten (W)). In one or more embodiments, the second dam structure 440 may include two layers that are vertically stacked. A lower layer of the two layers may be formed of or include copper (Cu). An upper layer of the two layers may be formed of or include nickel (Ni) or gold (Au). However, embodiments are not limited thereto, the second dam structure 440 may be composed of three or more layers or a single layer. The second dam structure 440 may be formed of or include the same material as the first dam structure 400.

The first heat transfer layer 410 may be disposed on the top surface of the upper redistribution layer 130 and in the inner region of the first dam structure 400. The kind and placement of the first heat transfer layer 410 may be the same as those described above. In one or more embodiments, the first heat transfer layer 410 may be provided on the center region CA of the heat radiator 300. In a plan view, the first dam structure 400 may enclose the first heat transfer layer 410.

The second heat transfer layer 420 may be disposed on the top surface of the upper redistribution layer 130 and outside the first dam structure 400. The second heat transfer layer 420 may be provided between the first and second dam structures 400 and 440. In other words, the second heat transfer layer 420 may be provided between the outer side surface of the first dam structure 400 and the inner side surface of the second dam structure 440.

In a plan view, the second heat transfer layer 420 may overlap the peripheral region SA of the heat radiator 300. An inner side surface of the second heat transfer layer 420 may contact the outer side surface of the first dam structure 400. In a plan view, the second heat transfer layer 420 may enclose the first dam structure 400. An outer side surface of the second heat transfer layer 420 may contact the inner side surface of the second dam structure 440. In a plan view, the second dam structure 440 may enclose the second heat transfer layer 420. The second heat transfer layer 420 may fill a region between the peripheral region SA of the bottom surface of the heat radiator 300 and the upper redistribution layer 130. In other words, the first heat transfer layer 410 may fill the region between the upper redistribution layer 130 and the center region CA of the heat radiator 300, and the second heat transfer layer 420 may fill a region between the upper redistribution layer 130 and the peripheral region SA of the heat radiator 300.

Positions of the first and second heat transfer layers 410 and 420 on the upper redistribution layer 130 may be defined by the first and second dam structures 400 and 440. That is, the first and second dam structures 400 and 440 may define regions, on which the first and second heat transfer layers 410 and 420 are formed.

In the description described with reference to FIG. 6, the second dam structure 440 is described to have a closed tetragonal ring shape in a plan view, but embodiments are not limited thereto. The shape and number of the second dam structure 440 may be variously changed, as described with reference to FIGS. 3 and 4.

In FIG. 6, the top surface of the second dam structure 440 is illustrated to contact the heat radiator 300, but embodiments are not limited thereto. The second heat transfer layer 420 may include a protruding portion that extends to a region on the top surface of the first dam structure 400. The second heat transfer layer 420 may cover at least a portion of the top surface of the second dam structure 440. Here, the heat radiator 300 may be attached to the second dam structure 440 by the second heat transfer layer 420 on the top surface of the second dam structure 440. Alternatively, the heat radiator 300 may be attached to the top surface of the second dam structure 440 using fourth connection terminals. The fourth connection terminals may be provided to have substantially the same features as the third connection terminals described with reference to FIG. 5.

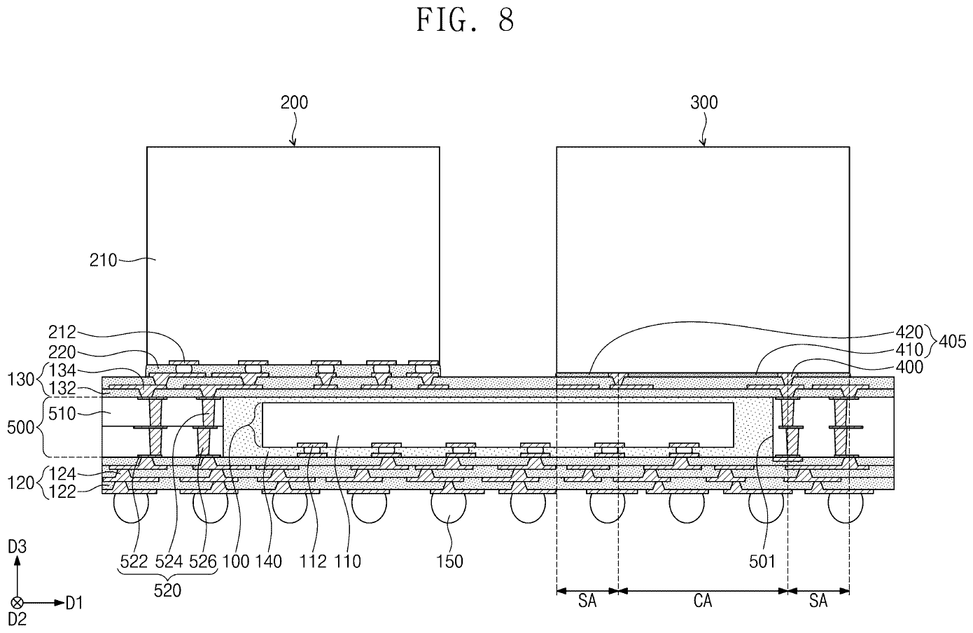

FIG. 8 is a cross-sectional view illustrating a semiconductor package according to one or more embodiments. Referring to FIG. 8, a connection substrate 500, instead of the metal post 142 (e.g., see FIG. 1), may be provided in the semiconductor package. The connection substrate 500 may correspond to a connection member, which is provided near the first semiconductor chip 100 to connect the lower redistribution layer 120 to the upper redistribution layer 130. The connection substrate 500 may be disposed on the lower redistribution layer 120. The connection substrate 500 may have an opening 501. For example, the opening 501 may have an open hole shape. The bottom surface of the connection substrate 500 may contact the top surface of the lower redistribution layer 120. The connection substrate 500 may include a base layer 510 and a conductive portion 520, which is an interconnection pattern provided in the base layer 510. The conductive portion 520 may be an interconnection element vertically connecting the lower redistribution layer 120 to the upper redistribution layer 130. The conductive portion 520 may be disposed in an outer region of the connection substrate 500. The conductive portion 520 may include lower pads 522, vias 524, and upper pads 526. The lower pads 522 may be disposed in a lower portion of the connection substrate 500. FIG. 8 illustrates an example, in which the lower interconnection pattern 124 of the lower redistribution layer 120 is directly connected to the lower pad 522 of the connection substrate 500, but embodiments are not limited thereto. Pads, which are connected to the lower interconnection pattern 124, may be provided on the top surface of the lower redistribution layer 120, and the connection substrate 500 may be mounted on the pads of the lower redistribution layer 120 using terminals (e.g., solder balls or solder bumps) provided on the lower pads 522. The description that follows will be given based on the embodiment of FIG. 8.

The upper pads 526 may be exposed to the outside of the connection substrate 500 near the top surface of the connection substrate 500. Alternatively, the upper pads 526 may have a protruding structure that extends to a region on the top surface of the connection substrate 500. The upper pads 526 may be electrically connected to the upper interconnection pattern 134 of the upper redistribution layer 130. The vias 524 may be provided to penetrate the base layer 510 to electrically connect the lower pads 522 to the upper pads 526.

The lower pads 522 may be disposed on the bottom surface of the connection substrate 500. The lower pads 522 may be placed in the base layer 510, and a bottom surface of the lower pads 522 may be coplanar with the bottom surface of the connection substrate 500. The vias 524 may be provided to penetrate the base layer 510 to electrically connect the upper pads 526 to the lower pads 522. The base layer 510 may include a polymer. For example, the base layer 510 may include an insulating polymer or a photoimageable dielectric (PID) material. In one or more embodiments, the PID material may include at least one of photoimageable polyimide, polybenzoxazole (PBO), phenol-based polymers, or benzocyclobutene-based polymers. In one or more embodiments, the base layer 510 may include an insulating material. For example, the base layer 510 may be formed of or include at least one of silicon oxide (SiO), silicon nitride (SiNx), silicon oxynitride (SiON), or insulating polymers. The upper pads 526, the lower pads 522, and the vias 524 may include a metal or conductive material (e.g., copper (Cu)).

The first semiconductor chip 100 may be disposed on the lower redistribution layer 120. The first semiconductor chip 100 may be disposed in the opening 501 of the connection substrate 500. Here, the first semiconductor chip 100 may be provided to have the same or similar structure as that described with reference to FIG. 1. The first semiconductor chip 100 may be spaced apart from an inner side surface of the opening 501. A side surface of the first semiconductor chip 100 may face the inner side surface of the opening 501. The mold layer 140 may be provided to fill a space between the first semiconductor chip 100 and the connection substrate 500. In more detail, the mold layer 140 may fill a space between the inner side surface of the opening 501 and the side surface of the connection substrate 500.

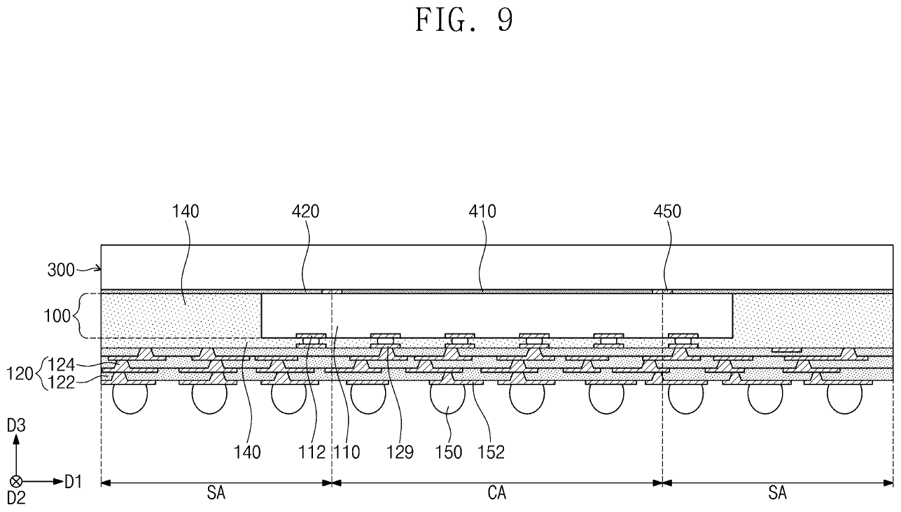

FIG. 9 is a cross-sectional view illustrating a semiconductor package according to one or more embodiments. Description of aspects that are the same as or similar to those described above may be omitted.

Referring to FIG. 9, the lower redistribution layer 120 may be provided. The outer connection terminal 150 may be disposed on a second substrate pad 152, which is provided on the bottom surface of the lower redistribution layer 120. The first semiconductor chip 100 may be provided on the lower redistribution layer 120. Here, the lower redistribution layer 120, the outer connection terminal 150, and the first semiconductor chip 100 may be provided to have substantially the same features as described with reference to FIG. 1. For example, the first semiconductor chip 100 may be mounted on the first substrate pad 129 of the lower redistribution layer 120 using the first connection terminal.

The mold layer 140 may be provided on the lower redistribution layer 120. The mold layer 140 may cover the top surface of the lower redistribution layer 120. The mold layer 140 may enclose the first semiconductor chip 100. The mold layer 140 may include an insulating material. For example, the mold layer 140 may include an epoxy molding compound (EMC). The top surface of the mold layer 140 may be coplanar with a top surface of the first semiconductor chip 100.

The semiconductor package of FIG. 9 may not include the metal post 142, the upper redistribution layer 130, and second semiconductor chip 200 of FIG. 1. The heat radiator 300 may be provided on the first semiconductor chip 100 and the mold layer 140. The heat radiator 300 may cover the top surface of the first semiconductor chip 100 and the top surface of the mold layer 140. The heat radiator 300 may include the center region CA and the peripheral region SA enclosing the center region CA. The center and peripheral regions CA and SA may contact each other and may be provided to have an interface therebetween. The heat radiator 300 may include at least one of materials having high thermal conductivity (e.g., metallic materials, ceramic materials, carbon materials, or polymer materials). Heat, which is generated in the first semiconductor chip 100, may be quickly dissipated to a region on the first semiconductor chip 100 through the heat radiator 300 with a large sectional area.

A third dam structure 450 may be provided on the top surface of the first semiconductor chip 100. The third dam structure 450 may include a protruding portion that extends to a region on the top surface of the first semiconductor chip 100. The third dam structure 450 may have outer and inner side surfaces that are opposite to each other and have a flat shape. In a plan view, the third dam structure 450 may have a closed-loop shape. More specifically, in a plan view, the third dam structure 450 may have a tetragonal ring shape. In a plan view, the third dam structure 450 may overlap the boundary between the center and peripheral regions CA and SA of the heat radiator 300. The third dam structure 450 may define the center and peripheral regions CA and SA of the heat radiator 300. That is, an inner region of the third dam structure 450, which is defined by the inner side surface of the third dam structure 450, may overlap the center region CA of the heat radiator 300. In a plan view, a region, which is defined by the outer side surface of the third dam structure 450 and the side surfaces of the heat radiator 300, may overlap the peripheral region SA of the heat radiator 300. A height of the third dam structure 450 in the third direction D3 may be equal to or smaller than a distance from the top surface of the first semiconductor chip 100 to the bottom surface of the heat radiator 300. In one or more embodiments, a top surface of the third dam structure 450 may contact the bottom surface of the heat radiator 300. The contact surface between the heat radiator 300 and the third dam structure 450 may be flat.

The third dam structure 450 may be formed of or include at least one of metallic materials (e.g., nickel (Ni), copper (Cu), gold (Au), aluminum (Al), and tungsten (W)). The third dam structure 450 may include two layers that are vertically stacked. A lower layer of the two layers may be formed of or include copper (Cu). An upper layer of the two layers may be formed of or include nickel (Ni) and gold (Au). However, embodiments are not limited thereto, and the third dam structure 450 may be composed of three or more layers or a single layer. The third dam structure 450 may be formed of or include the same material as the first dam structure 400 of FIG. 1, but embodiments are not limited thereto.

The first and second heat transfer layers 410 and 420 may be disposed on the top surface of the first semiconductor chip 100 and the top surface of the mold layer 140. The kind of the first and second heat transfer layers 410 and 420 may be similar to that in the embodiment described with reference to FIG. 1. For example, the first and second heat transfer layers 410 and 420 may include a thermal interface material (TIM), and the thermal conductivity of the first heat transfer layer 410 may be higher than the thermal conductivity of the second heat transfer layer 420.

The first heat transfer layer 410 may be provided inside the perimeter of the third dam structure 450 to fill a space between the top surface of the first semiconductor chip 100 and the center region CA of the heat radiator 300. The inner side surface of the third dam structure 450 may contact the side surface of the first heat transfer layer 410. In a plan view, the third dam structure 450 may enclose the first heat transfer layer 410. The second heat transfer layer 420 may be provided outside the perimeter of the third dam structure 450 to fill a space between the top surface of the first semiconductor chip 100 and the peripheral region SA of the heat radiator 300. The outer side surface of the third dam structure 450 may contact a side surface of the second heat transfer layer 420. In a plan view, the second heat transfer layer 420 may enclose the third dam structure 450.

In FIG. 9, the heat radiator 300 is illustrated to cover the top surface of the mold layer 140 and the top surface of the first semiconductor chip 100, but embodiments are not limited thereto. A width of the heat radiator 300 in the first direction D1 may be changed, if necessary. For example, the width of the heat radiator 300 may be substantially equal to or smaller than a width of the first semiconductor chip 100 in the first direction D1.

In FIG. 9, the top surface of the third dam structure 450 is illustrated to contact the bottom surface of the heat radiator 300, but embodiments are not limited thereto. For example, the first and second heat transfer layers 410 and 420 may cover the top surface of the third dam structure 450. Here, the heat radiator 300 may be attached to the third dam structure 450 by the first and second heat transfer layers 410 and 420 on the top surface of the first dam structure 400. Alternatively, the heat radiator 300 may be attached to the third dam structure 450 using a connection terminal (e.g., a solder ball) provided on the top surface of the heat radiator 300.

In FIG. 9, the first heat transfer layer 410 is illustrated to be disposed on the center region CA of the heat radiator 300, the second heat transfer layer 420 is illustrated to be disposed on the peripheral region SA of the heat radiator 300, but embodiments are not limited thereto. The positions of the first and second heat transfer layers 410 and 420 may be exchanged. For example, the second heat transfer layer 420 may be disposed in the inner region of the first dam structure 400 to fill a space between the upper redistribution layer 130 and the center region CA of the heat radiator 300, and the first heat transfer layer 410 may be disposed in the outer region of the first dam structure 400 to fill a space between the upper redistribution layer 130 and the peripheral region SA of the heat radiator 300.

In FIG. 9, the third dam structure 450 is illustrated to have the closed-loop shape, but the number and shape of the third dam structure 450 may be variously changed, if necessary, as described with reference to FIGS. 3 and 4.

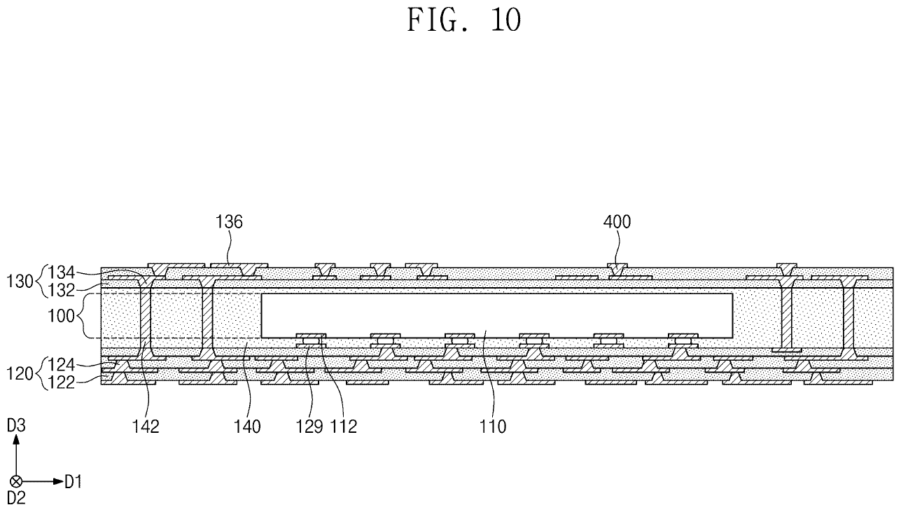

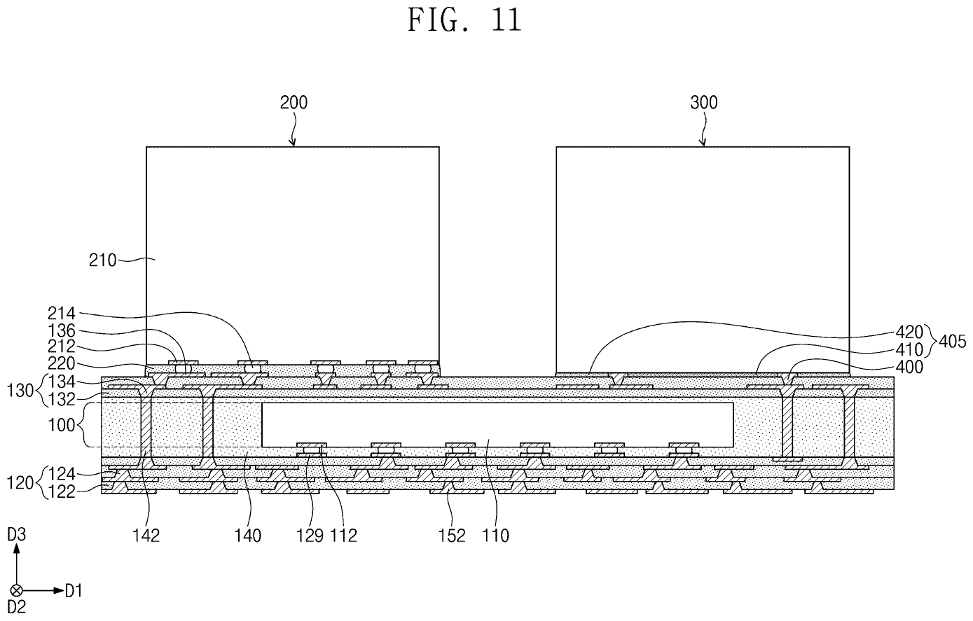

FIGS. 10 and 11 are cross-sectional views illustrating a method of fabricating a semiconductor package, according to one or more embodiments. Referring to FIG. 10, the lower redistribution layer 120 may be formed. For example, the lower insulating pattern 122 may be formed by forming and patterning an insulating layer. The lower interconnection pattern 124 may be formed by forming a conductive layer on the insulating layer and patterning the conductive layer. Here, the lower interconnection pattern 124 may include a protruding portion that is exposed to a region on the lower insulating pattern 122. Each lower interconnection layer may be formed by the afore-described process, and the lower redistribution layer 120, which includes a plurality of lower interconnection layers, may be formed by repeating the afore-described process.

The resulting structure formed by the processes may be inverted. The lower interconnection pattern 124 of the lower interconnection layer, which is placed at the uppermost level of the inverted structure, may serve as the first substrate pad 129, which is used to mount the first semiconductor chip 100 on the lower redistribution layer 120.

The first semiconductor chip 100 may be provided on the lower redistribution layer 120. Here, the first semiconductor chip 100 may be disposed in such a way that its active surface faces the lower redistribution layer 120. The first semiconductor chip 100 may be mounted on the lower redistribution layer 120 in a flip chip manner. The mold layer 140 may be formed on the lower redistribution layer 120. The mold layer 140 may fill a region between the lower redistribution layer 120 and the first semiconductor chip 100. For example, the mold layer 140 may be formed by forming an insulating material between the lower redistribution layer 120 and the first semiconductor chip 100 and curing the insulating material.

The metal post 142 may be formed in the mold layer 140. For example, a penetration hole may be formed to penetrate the mold layer 140 and to expose the lower interconnection pattern 124. The metal post 142 may be formed by filling the penetration hole with a conductive material.

The upper redistribution layer 130 may be formed on the top surface of the mold layer 140. For example, the upper insulating pattern 132 and the upper interconnection pattern 134 constituting the upper redistribution layer 130 may be formed on the top surface of the mold layer 140. In more detail, an insulating layer may be formed on the top surface of the mold layer 140 and may be patterned to form the upper insulating pattern 132. A conductive layer may be formed on the insulating layer and may be patterned to form the upper interconnection pattern 134. Here, a portion of the upper interconnection pattern 134 may be exposed to a region on the upper insulating pattern 132. Each upper interconnection layer may be formed by the afore-described process, and the upper redistribution layer 130, which includes a plurality of upper interconnection layers, may be formed by repeating the afore-described process.

The third substrate pad 136 and the first dam structure 400 may be formed on the top surface of the upper redistribution layer 130. For example, the third substrate pad 136 and the first dam structure 400 may be formed by patterning the conductive layer of the uppermost one of the upper interconnection layers. In one or more embodiments, the third substrate pad 136 and the first dam structure 400 may be formed simultaneously using the same process.

Referring to FIG. 11, the second semiconductor chip 200 may be provided on the upper redistribution layer 130. The second semiconductor chip 200 may be mounted on the upper redistribution layer 130 in a flip chip manner. The second semiconductor chip 200 may be provided to have substantially the same features as described with reference to FIG. 1. For example, the second semiconductor chip 200 may include the second semiconductor substrate 210 and the second connection terminal 214.

The first and second heat transfer layers 410 and 420 may be formed on the top surface of the upper redistribution layer 130. The formation of the first and second heat transfer layers 410 and 420 may include coating with the top surface of the upper redistribution layer 130 with a thermal interface material (TIM). The first heat transfer layer 410 may be formed inside the first dam structure 400, and the second heat transfer layer 420 may be formed outside the first dam structure 400. That is, the first heat transfer layer 410 may be inside a perimeter of the first dam structure 400 in a plan view, and the second heat transfer layer 420 may be outside the perimeter of the first dam structure 400 in the plan view.

The heat radiator 300 may be provided on the upper redistribution layer 130. The heat radiator 300 may be disposed on the first and second heat transfer layers 410 and 420 and may be spaced apart from the second semiconductor chip 200. The boundary between the center and peripheral regions CA and SA of the heat radiator 300 may overlap the first dam structure 400. The first and second heat transfer layers 410 and 420 may fill a region between the heat radiator 300 and the upper redistribution layer 130. A thermal process may be further performed to supply heat to the upper redistribution layer 130. As a result of the thermal process, the heat radiator 300 may be attached to the upper redistribution layer 130 by the first and second heat transfer layers 410 and 420.

Referring back to FIG. 1, the outer connection terminal 150 may be formed on the bottom surface of the lower redistribution layer 120. The outer connection terminal 150 may be formed on a bottom surface of the second substrate pad 152 and may be electrically connected to the second substrate pad 152. The semiconductor package of FIG. 1 may be fabricated through the afore-described process.

According to one or more embodiments, a semiconductor package may include a dam structure disposed on a substrate. The dam structure may be provided between the substrate and a heat radiator, and in this case, the heat-dissipation characteristics of the semiconductor package may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package, comprising:
a lower redistribution layer;
an outer connection terminal on a bottom surface of the lower redistribution layer;
a first semiconductor chip on the lower redistribution layer;
a mold layer enclosing the first semiconductor chip;
an upper redistribution layer on the mold layer and over a top surface of the first semiconductor chip;
a connection member connecting the lower redistribution layer and the upper redistribution layer;
a second semiconductor chip on the upper redistribution layer;
a heat radiator on the upper redistribution layer and horizontally spaced apart from the second semiconductor chip, the heat radiator comprising a center region and a peripheral region enclosing the center region;
a heat transfer structure between the upper redistribution layer and the heat radiator; and
a first dam structure between the upper redistribution layer and the heat radiator,
wherein, in plan view, the first dam structure has a closed-loop shape extending along a boundary between the center region and the peripheral region of the heat radiator, and
wherein the heat transfer structure comprises:
a first heat transfer layer inside a perimeter of the first dam structure in plan view and filling a first region between the upper redistribution layer and the heat radiator; and
a second heat transfer layer outside the perimeter of the first dam structure and filling a second region between the upper redistribution layer and the heat radiator.

2. The semiconductor package of claim 1, wherein a thermal conductivity of the first heat transfer layer is higher than a thermal conductivity of the second heat transfer layer.

3. The semiconductor package of claim 1, wherein the first heat transfer layer has an adhesion strength that is equal to or lower than an adhesion strength of the second heat transfer layer.

4. The semiconductor package of claim 1, wherein the mold layer fills a space between the lower redistribution layer and the upper redistribution layer, and
wherein the connection member comprises a metal post penetrate the mold layer and connecting the lower redistribution layer and the upper redistribution layer.

5. The semiconductor package of claim 1, further comprising a connection substrate between the lower redistribution layer and the upper redistribution layer, the connection substrate comprising an opening,
wherein the first semiconductor chip is in the opening of the connection substrate,
wherein the mold layer fills a region in the opening that is between the connection substrate and the first semiconductor chip, and
wherein the connection member comprises an interconnection pattern.

6. The semiconductor package of claim 1, further comprising a second dam structure between the upper redistribution layer and the heat radiator,
wherein, in plan view, the second dam structure has a closed-loop shape, encloses the first dam structure and is spaced apart from the first dam structure, and
wherein the second heat transfer layer is between the first dam structure and the second dam structure.

7. The semiconductor package of claim 1, wherein a top surface of the first heat transfer layer is substantially coplanar with a top surface of the second heat transfer layer, and
wherein the top surface of the first heat transfer layer and the top surface of the second heat transfer layer contact a bottom surface of the heat radiator.

8. The semiconductor package of claim 1, wherein the first dam structure has a tetragonal ring shape in plan view.

9. A semiconductor package, comprising:
an upper redistribution layer;
a first semiconductor chip on the upper redistribution layer;
a heat radiator on the upper redistribution layer and horizontally spaced apart from the first semiconductor chip;
a heat transfer structure between the upper redistribution layer and the heat radiator; and
a dam structure between the upper redistribution layer and the heat radiator,
wherein the dam structure comprises a protruding portion that extends to a top surface of the upper redistribution layer,
wherein the heat transfer structure comprises:
a first heat transfer layer; and
a second heat transfer layer adjacent to the first heat transfer layer, and
wherein, in plan view, the dam structure is between the first heat transfer layer and the second heat transfer layer.

10. The semiconductor package of claim 9, wherein a thermal conductivity of the first heat transfer layer is higher than a thermal conductivity of the second heat transfer layer.

11. The semiconductor package of claim 9, wherein a bottom surface of the heat radiator comprises a center region and a peripheral region,
wherein the first heat transfer layer contacts the center region of the bottom surface of the heat radiator and is within a perimeter of the dam structure, and
wherein the second heat transfer layer is outside the perimeter of the dam structure and contacts the peripheral region of the bottom surface of the heat radiator.

12. The semiconductor package of claim 9, further comprising:
a lower redistribution layer;
a second semiconductor chip between the lower redistribution layer and the upper redistribution layer; and
a mold layer enclosing the second semiconductor chip.

13. The semiconductor package of claim 9, wherein the dam structure has a closed, tetragonal ring shape in plan view, and
wherein the dam structure encloses a side surface of the first heat transfer layer.

14. The semiconductor package of claim 9, wherein the dam structure comprises a plurality of connection pads, and
wherein the plurality of connection pads are along an edge of the first heat transfer layer and are spaced apart from each other by a predetermined distance.

15. The semiconductor package of claim 14, wherein the plurality of connection pads are connected to the heat radiator by solder balls or solder bumps.

16. The semiconductor package of claim 9, wherein a width of the dam structure is in a range of 30 μm to 70 μm.

17. The semiconductor package of claim 9, wherein the dam structure comprises at least one of nickel (Ni), copper (Cu), gold (Au), aluminum (Al), and tungsten (W).

18. A semiconductor package, comprising:
a substrate;
a first semiconductor chip on the substrate;
a heat radiator on the substrate and horizontally spaced apart from the first semiconductor chip, the heat radiator comprising a center region and a peripheral region;
at least one dam structure comprising a first dam structure between the substrate and the first semiconductor chip and, in plan view, overlapping a boundary between the center region and the peripheral region of the heat radiator; and
a first heat transfer layer between the center region of the heat radiator and the substrate and within a perimeter of the first dam structure,
wherein the first dam structure comprises a metallic material.

19. The semiconductor package of claim 18, wherein the at least one dam structure comprises a plurality of dam structures comprising the first dam structure,
wherein the plurality of dam structures are spaced apart along an edge of the first heat transfer layer, and
wherein the plurality of dam structures enclose at least a portion of a side surface of the first heat transfer layer.

20. The semiconductor package of claim 18, further comprising:
a second heat transfer layer between the peripheral region of the heat radiator and the substrate;
wherein the at least one dam structure comprises a second dam structure between the heat radiator and the substrate, the second dam structure being vertically aligned with side surfaces of the heat radiator, and
wherein the second dam structure encloses a side surface of the second heat transfer layer.
